(19) United States
(12) Patent Application Publication
(10) Pub. No.: US 2021/0264078 A1
(43) Pub. Date: Aug. 26, 2021

(54) ROBUST OPTIMIZATION DESIGN METHOD FOR MECHANICAL ARM BASED ON HYBRID INTERVAL AND BOUNDED PROBABILISTIC UNCERTAINTIES

(71) Applicant: ZHEJIANG UNIVERSITY, Hangzhou City (CN)

(72) Inventors: Jin CHENG, Hangzhou City (CN); Zhenyu LIU, Hangzhou City (CN); Wei LU, Hangzhou City (CN); Jianrong TAN, Hangzhou City (CN)

(21) Appl. No.: 17/315,277

(22) Filed: May 8, 2021

Related U.S. Application Data
(63) Continuation of application No. PCT/CN2019/124148, filed on Dec. 9, 2019.

(30) Foreign Application Priority Data
Oct. 17, 2019 (CN) 201910987618.4

(51) Int. Cl. G06F 30/20; G06N 7/00

(52) U.S. Cl. CPC G06F 30/20; G06N 7/005

(57) ABSTRACT

A robust optimization design method for a mechanical arm considering hybrid interval and bounded probabilistic uncertainties is provided. The method includes considering interval and bounded probabilistic uncertainties affecting a performance of a mechanical arm, describing a bounded probabilistic uncertainty by a generalized beta distributed random variable, and establishing a robust optimization design model of the mechanical arm; directly solving the optimization model based on a genetic algorithm, which includes analyzing, by the boundedness of the uncertainties, the robustness of a constraint performance function of an individual in a population, and determining whether the individual is feasible; calculating, a mean and a standard deviation of an objective function of a feasible individual by multi-layered refining Latin hypercube sampling (MRLHS); and ranking, according to a total feasibility robustness index and a distance to negative ideal solution (DNIS), individuals in a current population to obtain a robust optimal design of the mechanical arm.

### TECHNICAL FIELD

The present disclosure belongs to the field of optimization design of equipment structures, and relates to a robust optimization design method for a mechanical arm based on hybrid interval and bounded probabilistic uncertainties.

### BACKGROUND

The size and joint positions of the mechanical arm directly affect the loading capacity, working efficiency and other performances of the mechanical arm. To ensure the working performance of the mechanical arm, it is necessary to optimize the lengths of the guide linkages and the joint positions in the mechanism after the length of the main structural linkage of the mechanical arm is determined.

There are usually a large number of uncertainties with various distribution characteristics in the design, manufacture and operation of the mechanical arm, which will deviate its performance from expectations. The state-of-the-art structural robust optimization design schemes usually only consider the probabilistic uncertainty or the interval uncertainty, and usually describe the probabilistic uncertainty by the normal distribution. The description of the normal distribution involves irrationality for engineering uncertainties. The theoretical negative values and positive infinity of normal distribution variables are inconsistent with the fact that realistic uncertain parameters only probabilistically fluctuate within a certain range. Meanwhile, in the solution process of the robust optimization design model that employs normal distribution variables to describe probabilistic uncertainties, the transformation and robustness assessment of the constraint performance function are usually conducted based on the 694 robust design criterion, and a weight factor is introduced to transform the uncertain objective performance function. Errors incurred in such model transformation inevitably lead to unreliable results of the robust optimization design, and the selection of the weight factor is subjective. In addition, the robustness analysis of the uncertain objective performance function is generally conducted based on Monte Carlo simulation (MCS), which is usually difficult to fully reflect the distribution characteristics of the probabilistic uncertainty involved in the objective performance function due to the loose distribution of sample points. Specifically, the existing sampling method does not offer sufficient samples in the domain of higher contribution near the mean point of the uncertain variable; on the contrary, it offers too much samples in the domain of lower contribution near the sampling bounds. This makes it difficult to guarantee the accuracy of the analysis result of the robustness of the objective performance function.

Therefore, the present disclosure proposes a method that integrates the robust optimization modeling of the mechanical arm, the accurate robustness assessment of the constraint performance function of the mechanical arm, the robustness analysis of the objective performance function and the efficient solution of the robust optimization model. This method can truly reflect the distribution characteristics of different types of uncertainties in practical engineering, avoid model transformation errors, effectively approximate the distribution characteristics of the probabilistic uncertainties, and effectively prevent a designer from subjective operations. In this way, the present disclosure can achieve a design scheme of a high-performance mechanical arm in actual operation.

### SUMMARY

In order to solve the problem of robust optimization design of a mechanical arm under the joint influence of interval and probabilistic uncertainties, the present disclosure provides a robust optimization design method for a mechanical arm based on hybrid interval and bounded probabilistic uncertainties. The present disclosure considers uncertainties in a hydraulic cylinder pressure, manufacturing precision and a material property of the mechanical arm and classifies them into an interval uncertainty and a probabilistic uncertainty, describes the probabilistic uncertainty by a generalized beta (GBeta) distribution and establishes a robust optimization design model of the mechanical arm with hybrid interval and bounded probabilistic uncertainties. Then the present disclosure directly solves the robust optimization model based on a genetic algorithm (GA). First, for all individuals, a robustness analysis is conducted on a constraint performance function based on the boundedness of the hybrid uncertainties, and the individuals in a current population are classified according to an analysis result. Second, for every feasible individual, a mean and a standard deviation of an objective performance function are calculated by a Monte Carlo approach based on multi-layered refining Latin hypercube sampling (MRLHS). Finally, based on a total feasibility robustness index of the constraint performance function and a distance to negative ideal solution (DNIS), the individuals in the current population are directly ranked to locate the optimal one. In this way, the present disclosure efficiently solves the problem of robust optimization design of the mechanical arm under the joint influence of interval and probabilistic uncertainties.

The present disclosure is achieved by a technical solution as follows: a robust optimization design method for a mechanical arm based on hybrid interval and bounded probabilistic uncertainties includes the following steps:

1) considering uncertainties in a cylinder pressure, manufacturing precision and a material property of a mechanical arm and classifying them into interval and bounded probabilistic uncertainties, and describing each bounded probabilistic uncertain variable as a random variable subjected to a generalized beta distribution (GBeta distribution), specifically:

1.1) obtaining, for a bounded probabilistic uncertain variable Xᵢ, s samples through an experiment to construct a sample point set {Xᵢ¹, Xᵢ², . . . , Xᵢ^{s}}; calculating, based on the sample point set, a value range of the variable Xᵢ by Eq. 1, and calculating a mean and a variance of the variable Xᵢ by Eq. 2:

$$\begin{matrix}\{ \begin{matrix}{a}_{i} = min \{ {X}_{i}^{1} , {X}_{i}^{2} , … , {X}_{i}^{s} \} \\ {b}_{i} = max \{ {X}_{i}^{1} , {X}_{i}^{2} , … , {X}_{i}^{s} \}\end{matrix} , and & Eq . 1 \\ \{ \begin{matrix}{{μ}_{X}}_{i} = \frac{1}{s} {\sum }_{k = 1}^{s} {X}_{i}^{k} \\ {S}_{{X}_{i}}^{2} = \frac{1}{s} {\sum }_{k = 1}^{s} {( {X}_{i}^{k} - {μ}_{{X}_{i}} )}^{2}\end{matrix} ; & Eq . 2\end{matrix}$$

1.2) describing, by the GBeta distribution, the variable Xᵢ that is distributed within [aᵢ, bᵢ] and has a mean of μ_{X}_{ᵢ} and a variance of S_{X}_{ᵢ}²; firstly, normalizing the mean and the variance of the variable Xᵢ by Eq. 3:

$$\{ \begin{matrix}{\hat{μ}}_{{X}_{i}} = \frac{{μ}_{{X}_{i}} - {a}_{i}}{{b}_{i} - {a}_{i}} \\ {\hat{S}}_{{X}_{i}}^{2} = \frac{{S}_{{X}_{i}}^{2}}{{( {b}_{i} - {a}_{i} )}^{2}}\end{matrix} , \qquad Eq . 3$$

then, calculating distribution parameters αᵢ and βᵢ of the GBeta distribution of the variable Xᵢ by Eq. 4:

$$\{ \begin{matrix}{α}_{i} = \frac{1 - {\hat{μ}}_{{X}_{i}}}{1 + {\hat{μ}}_{{X}_{i}}} \cdot \frac{1}{{\hat{S}}_{{X}_{i}}^{2}} \\ {β}_{i} = \frac{{( 1 - {\hat{μ}}_{{X}_{i}} )}^{2}}{{\hat{μ}}_{{X}_{i}} ( 1 + {\hat{μ}}_{{X}_{i}} )} \cdot \frac{1}{{\hat{S}}_{{X}_{i}}^{2}}\end{matrix} , \qquad Eq . 4$$

denoting the variable Xᵢ subjected to the GBeta distribution within [aᵢ, bᵢ] with the distribution parameters αᵢ and βᵢ as Xᵢ˜GBeta(aᵢ, bᵢ|αᵢ, βᵢ), where a probabilistic density function of the variable Xᵢ is defined by Eq. 5:

$${f}_{{X}_{i}} ( {X}_{i} ; {α}_{i} , {β}_{i} \vert {a}_{i} , {b}_{i} ) = \frac{Γ ( {α}_{i} + {β}_{i} )}{Γ ( {α}_{i} ) Γ ( {β}_{i} )} {( \frac{1}{{b}_{i} - {a}_{i}} )}^{{α}_{i} + {β}_{i} - 1} \cdot {( {X}_{i} - {a}_{i} )}^{{α}_{i} - 1} {( {b}_{i} - {X}_{i} )}^{{β}_{i} - 1} , \qquad Eq . 5$$

where in Eq. 5, ƒ_{X}_{ᵢ}(⋅) is the probabilistic density function of the variable Xᵢ, and Γ(⋅) is a gamma function;

where the GBeta distribution and its probabilistic density function are first proposed to avoid irrationality caused by utilizing unbounded description of the probabilistic uncertainty. The basic principle is to retain the boundedness and controllability of distribution parameters of the beta distribution in the standard interval [0, 1], and map between the standard interval and the distribution interval of the realistic engineering probabilistic uncertain parameters through a linear transformation. The proposed GBeta distribution completely retains the probabilistic statistical information (mean and variance) of the engineering uncertain parameters, avoids the possibility of unreasonable values of the uncertain variables, and avoids model errors caused by the transformation of constraint functions in solving robust optimization models based on normal distribution.

2) establishing a robust optimization design model of the mechanical arm with the hybrid interval and bounded probabilistic uncertainties by taking a maximum loading capacity of the mechanical arm in operation under the influence of the hybrid interval and bounded probabilistic uncertainties as an optimization objective, and describing a performance index of the mechanical arm with a given maximum allowable value as a constraint performance function, the robust optimization design model being shown in Eq. 6:

$${min}_{d} \{ {μ}_{{f}^{C} ( d , X , U )} , {σ}_{{f}^{C} ( d , X , U )} , {μ}_{{f}^{W} ( d , X , U )} , {σ}_{{f}^{W} ( d , X , U )} \} \\ s . t . [ {g}_{i}^{{L}^{*}} ( d , X , U ) , {g}_{i}^{{R}^{*}} ( d , X , U ) ] \leq {B}_{i} = [ {b}_{i}^{L} , {b}_{i}^{R} ] , \\ i = 1 , 2 , … , p \\ d = ( {d}_{1} , {d}_{2} , … , {d}_{i} ) , \\ X = ( {X}_{1} , {X}_{2} , … , {X}_{m} ) , \\ U = ( {U}_{1} , {U}_{2} , … , {U}_{n} ) , \qquad Eq . 6$$

where in Eq. 6, d=(d₁, d₂, . . . , dₗ) l-dimensional design vector; X=(X₁, X₂, . . . , Xₘ) is an n-dimensional bounded probabilistic uncertain vector;

[symbol] (U₁, U₂, . . . , Uₙ) is an n-dimensional interval uncertain vector; Bᵢ is an interval constant given according to a design requirement; bᵢ^{L} and bᵢ^{R} are left and right bounds of Bᵢ respectively, and when bᵢ^{L}=bᵢ^{R}, the interval constant Bᵢ degenerates to a real number; p is a number of constraint performance functions; gᵢ^{L*}(d, X, U) and gᵢ^{R*}(d, X, U) are respectively left and right bounds of a performance variation interval of an i-th constraint performance function gᵢ(d, X, U) under the influence of the hybrid interval and bounded probabilistic uncertainties, and gᵢ^{L*}(d, X, U) and gᵢ^{R*}(d, X, U) are calculated as follows:

a) rewriting the probabilistic uncertain vector X as an interval form X^{I}=(X₁^{I}, X₂^{I}, . . . , Xₘ^{I}) utilizing boundedness of the probabilistic uncertain vector X, wherein Xᵢ^{I}=[aᵢ, bᵢ] (i=1, 2, . . . , m) is an interval number corresponding to the bounded probabilistic uncertain variable Xᵢ; aᵢ, bᵢ are determined by Eq. 1; I is a mark of an interval representation form corresponding to the bounded probabilistic uncertain variable;

b) merging the interval vector U and the interval form X^{I} of the bounded probabilistic uncertain vector into a new interval uncertain vector, denoted as H_{U}^{X}^{^{I}}=(X^{I}, U), then, calculating gᵢ^{L*}(d, X, U) and gᵢ^{R*}(d, X, U) by Eq. 7:

$$\{ \begin{matrix}{g}_{i}^{{L}^{*}} ( d , X , U ) = {min}_{{H}_{U}^{{X}^{I}}} {g}_{i} ( d , {H}_{U}^{{X}^{I}} ) \\ {g}_{i}^{{R}^{*}} ( d , X , U ) = {min}_{{H}_{U}^{{X}^{I}}} {g}_{i} ( d , {H}_{U}^{{X}^{I}} )\end{matrix} ( i = 1 , 2 , … , p ) , \qquad Eq . 7$$

where the traditional method of describing uncertain parameters with unbounded probabilistic variables of normal distribution cannot examine all possible values of the uncertain variables. Consequently, 6σ transformation is generally adopted in the robustness analysis of the constraint function to estimate the variation interval of the constraint performance function. This process will inevitably produce transformation errors. In order to facilitate the proposed bounded probabilistic variables of GBeta distribution to describe uncertain parameter, the present disclosure creatively proposes a new assessment method, that is, to employ the boundedness of the probabilistic uncertain variables and unify the form with the interval uncertain variables. This method is convenient, direct and precise to calculate the left and right bounds of the variation interval of each constraint performance function, and greatly improves the accuracy of the robustness assessment of the constraint function;

where in Eq. 6, μ_{ƒ}_{^{C}}_{(d,X,U)}, σ_{ƒ}_{^{C}}_{(d,X,U)}, μ_{ƒ}_{^{W}}_{(d,X,U)}, σ_{ƒ}_{^{W}}_{(d,X,U)} respectively are a mean and a standard deviation of a center, and a mean and a standard deviation of a halfwidth of a variation interval of an objective performance function ƒ(d, X, U) under the influence of the bounded probabilistic uncertain vector X and the interval uncertain vector U, which are calculated as follows:

A) defining μ_{X}=(μ_{X}_{₁}, μ_{X}_{₂}, . . . , μ_{X}_{ₘ}) as a constant vector obtained by taking a mean of each probabilistic variable in the bounded probabilistic uncertain vector X, and denoting μ_{X} as a mean vector of the bounded probabilistic uncertain vector X; substituting the bounded probabilistic uncertain vector X in the objective performance function ƒ(d, X, U) with the mean vector μ_{X} to transform the objective performance function into a function ƒ(d, μ_{X}, U), which includes only the interval uncertain vector U and whose value is an interval number;

B) performing an interval analysis of ƒ(d, μ_{X}, U) through an interval analysis algorithm by Eq. 8 to obtain left and right bounds ƒ^{L}(d, μ_{X}) and ƒ^{R}(d, μ_{X}) of a variation interval of the objective performance function ƒ(d, μ_{X}, U) at the mean vector μ_{X}:

$$\{ \begin{matrix}{f}^{L} ( d , {μ}_{X} ) = {f}^{L} ( d , {μ}_{X} , U ) {\vert}_{U = {U}_{min}^{*}} = {min}_{U} f ( d , {μ}_{X} , U ) \\ {f}^{R} ( d , {μ}_{X} ) = {f}^{R} ( d , {μ}_{X} , U ) {\vert}_{U = {U}_{max}^{*}} = {max}_{U} f ( d , {μ}_{X} , U )\end{matrix} , \qquad Eq . 8$$

where in Eq. 8, U*ₘᵢₙ and U*ₘₐₓ are interval uncertain vectors to minimize and maximize ƒ(d, μ_{X}, U), respectively;

C) calculating, by Eq. 9, a center ƒ^{C}(d, μ_{X}) and a halfwidth ƒ^{W}(d, μ_{X}) of the variation interval of the objective performance function ƒ(d, μ_{X}, U) at the mean vector μ_{X}:

$$\{ \begin{matrix}{f}^{C} ( d , {μ}_{X} ) = ( {f}^{L} ( d , {μ}_{X} ) + {f}^{R} ( d , {μ}_{X} ) ) / 2 \\ {f}^{W} ( d , {μ}_{X} ) = ( {f}^{R} ( d , {μ}_{X} ) - {f}^{L} ( d , {μ}_{X} ) ) / 2\end{matrix} , \qquad Eq . 9$$

where in Eq. 9, ƒ^{L}(d, μ_{X}), ƒ^{R}(d, μ_{X}), ƒ^{C}(d, μ_{X}) and ƒ^{W}(d, μ_{X}) have no uncertain variable and each has a real-number value;

D) restoring μ_{X} in ƒ^{C}(d, μ_{X}) and ƒ^{W}(d, μ_{X}) to the bounded probabilistic uncertain vector X; performing multi-layered refining Latin hypercube sampling (MRLHS) within a probabilistic distribution range of the bounded probabilistic uncertain vector X; calculating a value of the objective performance function corresponding to each sample point, where the objective performance function corresponding to each sample point has no uncertainty and has a real-number value; calculating, by a Monte Carlo approach, the mean μ_{ƒ}_{^{C}}_{(d,X,U)} and standard deviation σ_{ƒ}_{^{C}}_{(d,X,U)} of the center and the mean μ_{ƒ}_{^{W}}_{(d,X,U)} and standard deviation σ_{ƒ}_{^{W}}_{(d,X,U)} of the halfwidth in the variation interval of the objective performance function ƒ(d, X, U) under the influence of the bounded probabilistic uncertain vector X and the interval uncertain vector U, specifically as follows:

D.1) determining an m-dimensional original sampling domain D^{m}=[a₁, b₁]×[a₂, b₂]× . . . ×[aₘ, bₘ], where aᵢ, bᵢ (i=1, 2, . . . , m) is a value range of the bounded probabilistic uncertain variable Xᵢ determined by Eq. 1, and × is a Cartesian product operator in a linear space;

D.2) constructing, by dividing and extracting the original sampling domain D^{m}, a mean neighborhood layer sampling domain δD_{μ}^{m} and a transitional layer sampling domain Dₜᵣₐₙ ^{m} to form three layers of sampling domains, namely D^{m}, δD_{μ}^{m} and Dₜᵣₐₙ^{m}:

δD_{μ}^{m}=[δX₁^{L},δX₁^{R}]×[δX₂^{L},δX₂^{R}]× . . . ×[δXₘ^{L},δXₘ^{R}] Eq. 10, and

Dₜᵣₐₙ^{m}=[X₁ₜ^{L},X₁ₜ^{R}]×[X₂ₜ^{L},X_{2f}^{R}]× . . . ×[Xₘₜ^{L},Xₘₜ^{R}] Eq. 11,

where in Eq. 10 and Eq. 11, δXᵢ^{L} and δXᵢ^{R} (i=1, 2, . . . , m) are left and right bounds of an i-th dimension in the m-dimensional mean neighborhood layer sampling domain δD_{μ}^{m} respectively; Xᵢₜ^{L} and Xᵢₜ^{R} (i=1, 2, . . . , m) are left and right bounds of the i-th dimension in the m-dimensional transitional layer sampling domain Dₜᵣₐₙ^{m} respectively; the left and right bounds are determined by Eq. 12:

$$\{ \begin{matrix}δ {X}_{i}^{L} = {F}_{{X}_{i}}^{- 1} ( 0.3 , {α}_{i} , {β}_{i} ) \\ δ {X}_{i}^{R} = {F}_{{X}_{i}}^{- 1} ( 0.7 , {α}_{i} , {β}_{i} ) \\ {X}_{it}^{L} = {F}_{{X}_{i}}^{- 1} ( 0.2 , {α}_{i} , {β}_{i} ) \\ {X}_{it}^{R} = {F}_{{X}_{i}}^{- 1} ( 0.8 , {α}_{i} , {β}_{i} )\end{matrix} ( i = 1 , 2 , … , m ) , \qquad Eq . 12$$

where in Eq. 12, F_{X}_{ᵢ}⁻¹(⋅) is an inverse function of a probabilistic cumulative function F_{X}_{ᵢ}(⋅) of the bounded probabilistic uncertain variable Xᵢ;

D.3) setting a total sample size to N, performing standard Latin hypercube sampling (LHS) with a size of N/3 in each of the three layers of sampling domains, and superimposing sample points of each layer to obtain a final sample point set;

D.4) calculating, by the Monte Carlo approach based on the obtained final sample point set, the mean μ_{ƒ}_{^{C}}_{(d,X,U)} and standard deviation σ_{ƒ}_{^{C}}_{(d,X,U)} of the center, and the mean μ_{ƒ}_{^{W}}_{(d,X,U)} and standard deviation σ_{ƒ}_{^{W}}_{(d,X,U)} of the halfwidth in the variation interval of the objective performance function ƒ(d, X, U) under the influence of the bounded probabilistic uncertain vector X and the interval uncertain vector U;

where the MRLHS method inventively proposed by the present disclosure retains the advantages of the traditional single-layered Latin hypercube sampling, and highlights the sample distribution with a higher contribution to the statistical parameters of the objective function near the mean point. According to a probabilistic cumulative function, the original sampling domain is further divided into the mean neighborhood layer sampling domain δD_{μ}^{m} near the mean point and the transitional layer sampling domain Dₜᵣₐₙ^{m}. This better reflects the actual performance of the objective performance function, and reduces samples with a lower contribution on the left and right bounds of the bounded probabilistic uncertain variable, thereby further improving the accuracy of the robustness assessment of the objective performance function; and

3) directly solving the robust optimization design model of the mechanical arm based on a genetic algorithm (GA), a total feasibility robustness index and a distance to negative ideal solution (DNIS):

3.1) setting GA parameters, including population size, maximum number of iterations, mutation and crossover probabilities, and convergence criterion; setting a current iteration number of the GA to 1, and generating an initial population of the GA;

3.2) performing robustness assessment for a constraint performance function of each individual in a current population, and calculating a total feasibility robustness index S corresponding to a design vector d;

3.3) classifying all the individuals in the current population according to the total feasibility robustness index S, and marking an individual as (a) feasible if S=p, (b) semi-feasible if 0<S<p and (c) infeasible if S=0;

3.4) calculating a mean and a standard deviation of an objective performance function corresponding to a feasible individual by an MRLHS-based Monte Carlo approach according to steps D.1) to D.4);

3.5) ranking, according to a classifying result of the individuals in the current population in step 3.3) and calculation results of the means and standard deviations of the objective performance function of the feasible individuals in step 3.4), all individuals in the current population based on the total feasibility robustness indices and the distances to negative ideal solution (DNIS_{S}) to obtain a fitness for each individual in the current population;

3.6) determining whether the maximum number of iterations or the convergence criterion is satisfied; if yes, outputting a design vector corresponding to an individual with a largest fitness as an optimal solution; if not, performing crossover and mutation operations, increasing the iteration number by 1 to produce a new generation of population individuals, and returning to step 3.2).

Further, in step D.4), the mean μ_{ƒ}_{^{C}}_{(d,X,U)} and the standard deviation σ_{ƒ}_{^{C}}_{(d,X,U)} of the center of the variation interval of the objective performance function ƒ(d, X, U) are calculated by Eq. 13:

$$\{ \begin{matrix}{μ}_{{f}^{C} ( d , X , U )} \approx \frac{1}{N} {\sum }_{k = 1}^{N} {f}^{C} ( d , {X}_{k} ) \\ {σ}_{{f}^{C} ( d , X , U )} \approx \sqrt{\frac{1}{N - 1} {\sum }_{k = 1}^{N} [ {f}^{C} ( d , {X}_{k} ) - {μ}_{{f}^{C} ( d , X , U )} {]}^{2}}\end{matrix} , \qquad Eq . 13$$

where in Eq. 13, N is the total sample size, and Xₖ (k=1, 2, . . . , N) is a k-th sample point in the final sample point set; and

the mean μ_{ƒ}_{^{W}}_{(d,X,U)} and the standard deviation σ_{ƒ}_{^{W}}_{(d,X,U)} of the halfwidth of the variation interval of the objective performance function ƒ(d, X, U) are calculated by Eq. 14:

$${S}_{i} = \begin{matrix} \{ \begin{matrix}{μ}_{{f}^{W} ( d , X , U )} \approx \frac{1}{N} {\sum }_{k = 1}^{N} {f}^{W} ( d , {X}_{k} ) \\ {σ}_{{f}^{W} ( d , X , U )} \approx \sqrt{\frac{1}{N - 1} {\sum }_{k = 1}^{N} [ {f}^{W} ( d , {X}_{k} ) - {μ}_{{f}^{W} ( d , X , U )} {]}^{2}}\end{matrix} . & Eq . 14\end{matrix}$$

Further, step 3.2) is specifically implemented as follows:

3.2.1) denoting Gᵢ^{CS}=(gᵢ^{L*}(d, X, U)+gᵢ^{R*}(d, X, U))/2 and Gᵢ^{WS}=(gᵢ^{R*}(d, X, U)−gᵢ^{L*}(d, X, U))/2 as a center and a halfwidth in a variation interval of the i-th constraint performance function gᵢ(d, X, U), and defining an interval angular vector of the constraint performance function gᵢ(d, X, U) as a_{G}_{ᵢ}_{^{S}}=(Gᵢ^{CS}, Gᵢ^{WS}), with a norm of ∥a_{G}_{ᵢ}_{^{S}}∥; denoting Bᵢ^{C}=(bᵢ^{L}+bᵢ^{R})/2 and Bᵢ^{W}=(bᵢ^{R}−bᵢ^{L})/2 as a center and a halfwidth of a given interval constant Bᵢ corresponding to the i-th constraint performance function gᵢ(d, X, U), and defining an interval angular vector of the constant Bᵢ as a_{B}_{ᵢ}=(Bᵢ^{C}, Bᵢ^{W}), with a norm of ∥a_{B}_{ᵢ}∥;

3.2.2) calculating a feasibility robustness index of the i-th constraint performance function gᵢ(d, X, U) by Eq. 15:

$$\{ \begin{matrix}1 - \frac{t r}{2} ( 1 - \frac{‖ {α}_{{G}_{i}^{S}} \times {α}_{{B}_{i}} ‖}{‖ {α}_{{G}_{i}^{S}} ‖ \cdot ‖ {α}_{{B}_{i}} ‖} ) - bia , {α}_{{B}_{i}} \neq ( 0 , 0 ) \\ 1 - \frac{t r}{2} ( 1 - \frac{‖ {α}_{{G}_{i}^{S}} \times {e}_{j} ‖}{‖ {α}_{{G}_{i}^{S}} ‖ \cdot ‖ {e}_{i} ‖} ) - bia , {α}_{{B}_{i}} \neq ( 0 , 0 )\end{matrix} , \qquad Eq . 15$$

where in Eq. 15, Sᵢ is the feasibility robustness index of the i-th constraint performance function gᵢ(d, X, U); eⱼ=(0, 1) is a unit vector; tr and bia respectively are a switch factor and a bias factor, which are calculated by Eq. 16:

$$\{ \begin{matrix}tr = \frac{1}{2} [ sign ( {g}_{i}^{{R}^{*}} ( d , X , U ) - {b}_{i}^{L} ) ( {b}_{i}^{R} - {g}_{i}^{{L}^{*}} ( d , X , U ) ) + 1 ] \\ bia = \frac{1}{2} [ sign ( {g}_{i}^{{L}^{*}} ( d , X , U ) - {b}_{i}^{R} ) + 1 ]\end{matrix} , \qquad Eq . 16$$

where, in Eq. 16, sign(⋅) is a sign function;

3.2.3) calculating, based on the feasibility robustness index of each constraint performance function, a total feasibility robustness index S of an individual by Eq. 17:

$$S = {\sum }_{i = 1}^{p} {S}_{i} , \qquad Eq . 17$$

where in Eq. 17, Sᵢ is the feasibility robustness index of the i-th constraint performance function gᵢ(d, X, U), and p is a number of the constraint performance functions.

Further, step 3.5) is specifically implemented as follows:

3.5.1) calculating the DNIS of each feasible individual respectively, and calculating the DNIS D*(d) of an individual corresponding to the design vector d by Eq. 18:

$${D}^{*} ( d ) = \sqrt{\begin{matrix}\frac{{( {μ}_{max}^{C} - {μ}_{{f}^{C} ( d , X , U )} )}^{2}}{{μ}_{max}^{C} - {μ}_{min}^{C}} + \frac{{( {σ}_{max}^{C} - {σ}_{{f}^{C} ( d , X , U )} )}^{2}}{{μ}_{max}^{C} - {μ}_{min}^{C}} + \\ \frac{{( {μ}_{max}^{W} - {μ}_{{f}^{W} ( d , X , U )} )}^{2}}{{μ}_{max}^{W} - {μ}_{min}^{W}} + \frac{{( {σ}_{max}^{W} - {σ}_{{f}^{W} ( d , X , U )} )}^{2}}{{μ}_{max}^{W} - {μ}_{min}^{W}}\end{matrix}} , \qquad Eq . 18$$

where, parameters in Eq. 18 are defined by Eq. 19:

$$\{ \begin{matrix}{μ}_{min}^{C} = min \{ {μ}_{{f}^{C} ( {d}_{1} , X , U )} , {μ}_{{f}^{C} ( {d}_{2} , X , U )} , … , {μ}_{{f}^{C} ( {d}_{{n}_{1}} , X , U )} \} \\ {μ}_{max}^{C} = max \{ {μ}_{{f}^{C} ( {d}_{1} , X , U )} , {μ}_{{f}^{C} ( {d}_{2} , X , U )} , … , {μ}_{{f}^{C} ( {d}_{{n}_{1}} , X , U )} \} \\ {σ}_{min}^{C} = min \{ {σ}_{{f}^{C} ( {d}_{1} , X , U )} , {σ}_{{f}^{C} ( {d}_{2} , X , U )} , … , {σ}_{{f}^{C} ( {d}_{{n}_{1}} , X , U )} \} \\ {σ}_{max}^{C} = max \{ {σ}_{{f}^{C} ( {d}_{1} , X , U )} , {σ}_{{f}^{C} ( {d}_{2} , X , U )} , … , {σ}_{{f}^{C} ( {d}_{{n}_{1}} , X , U )} \} \\ {μ}_{min}^{W} = min \{ {μ}_{{f}^{W} ( {d}_{1} , X , U )} , {μ}_{{f}^{W} ( {d}_{2} , X , U )} , … , {μ}_{{f}^{W} ( {d}_{{n}_{1}} , X , U )} \} \\ {μ}_{max}^{W} = max \{ {μ}_{{f}^{W} ( {d}_{1} , X , U )} , {μ}_{{f}^{W} ( {d}_{2} , X , U )} , … , {μ}_{{f}^{W} ( {d}_{{n}_{1}} , X , U )} \} \\ {σ}_{min}^{W} = min \{ {σ}_{{f}^{W} ( {d}_{1} , X , U )} , {σ}_{{f}^{W} ( {d}_{2} , X , U )} , … , {σ}_{{f}^{W} ( {d}_{{n}_{1}} , X , U )} \} \\ {σ}_{max}^{W} = max \{ {σ}_{{f}^{W} ( {d}_{1} , X , U )} , {σ}_{{f}^{W} ( {d}_{2} , X , U )} , … , {σ}_{{f}^{W} ( {d}_{{n}_{1}} , X , U )} \}\end{matrix} , \qquad Eq . 19$$

where in Eq. 19, d₁, d₂ , . . . , dₙ_{₁} are all design vectors corresponding to the feasible individuals in the current population, and n₁ is a total number of the feasible individuals;

3.5.2) ranking the feasible individuals and the semi-feasible individuals, so that each individual participating in the ranking obtains a unique sequence number and an individual with inferior objective or constraint performance robustness has a larger sequence number, specifically:

a) ranking the feasible individuals in a descending order of the DNIS D*(d) from largest to smallest, where a smaller D*(d) indicates an inferior objective performance and a larger sequence number of the corresponding feasible individual, that is, the sequence numbers of the feasible individuals dₐ₁, dₐ₂, . . . , dₐₙ_{₁} satisfying D*(dₐ₁)≥D*(dₐ₂)≥ . . . ≥D*(dₐₙ_{₁}) are 1, 2, . . . , n₁ respectively; n₁ is a number of the feasible individuals in the current population; a indicates that the individual is feasible;

b) ranking the semi-feasible individuals in a descending order of the total feasibility robustness index S from largest to smallest, where a smaller S indicates that the corresponding semi-feasible individual has inferior robustness of the constraint performance function and has a larger sequence number; when the feasible individuals and the semi-feasible individuals are ranked, the sequence number of a first semi-feasible individual closely follows the sequence number of a last feasible individual; the sequence numbers of the two types of individuals are continuous, and the sequence numbers of the semi-feasible individuals are greater than the sequence numbers of the feasible individuals, that is, the sequence numbers of the semi-feasible individuals d_{b1}, d_{b2}, . . . , d_{bn}_{₂} satisfying S(d_{b1})≥S(d_{b2})≥ . . . ≥S(d_{bn}_{₂}) are (n₁+1), (n₁+2), . . . , (n₁+n₂) respectively; n₂ is a number of the semi-feasible individuals in the current population; b indicates that the individual is semi-feasible; and

3.5.3) calculating the fitness of each individual in the current population: a) calculating the fitness of a feasible individual or a semi-feasible individual according to its sequence number of ranking in step 3.5.2), and setting the fitness of a design vector with a sequence number i to 1/i; and b) setting the fitness of every infeasible individual to 0.

The present disclosure has the following beneficial effects:

1) The present disclosure describes the distribution characteristics of multi-source uncertainties in the cylinder pressure, manufacturing precision and material property of the mechanical arm as an interval variable or a bounded probabilistic variable subjected to the GBeta distribution, and establishes a robust optimization design model of the mechanical arm with hybrid interval and bounded probabilistic uncertain variables. The present disclosure overcomes the shortcomings of the existing robust design method that only considers probabilistic variables or interval variables, and avoids the irrationality caused by utilizing normally distributed random variables to describe probabilistic uncertain factors. Therefore, the robust optimization model of the mechanical arm established by the present disclosure is more coincident with engineering reality.

2) The present disclosure employs bounded probabilistic variables subjected to the GBeta distribution to describe probabilistic uncertainties, so that the value of the constraint performance function of the mechanical arm affected by the hybrid interval and probabilistic uncertainties fluctuates in a bounded probabilistic manner. The robustness of the constraint performance function can be directly assessed based on the upper and lower bounds of the fluctuation under the influence of the hybrid interval and probabilistic uncertainties. This avoids the simplification error incurred by the transformation of the constraint performance function based on the 6σ robust design criterion in the description of the probabilistic uncertain parameters by the normal distribution variables, and obtains a more accurate result of robustness assessment of the constraint performance function.

3) The present disclosure employs an MRLHS-based Monte Carlo simulation (MCS) to analyze the robustness of the objective performance function of the mechanical arm. This approach obtains more samples with a higher contribution in the mean neighborhood with no increase of the sample size, and reduces samples with a lower contribution at the boundary of the uncertain variation range. The present disclosure overcomes the shortcoming of too loose distribution of sample points generated by traditional LHS, reflects the distribution characteristics of probabilistic uncertainties more accurately and fully, and improves the accuracy of the MCS-based robustness analysis result of the objective performance function of the mechanical arm.

4) The present disclosure employs the efficient and stable GA to directly solve the robust optimization design model of the mechanical arm. The present disclosure classifies the individuals in a population based on the total feasibility robustness indexes of all constraint performance functions, and directly ranks the population individuals according to the DNIS_{S} of the objective performance function to locate the optimal solution. The present disclosure overcomes the shortcoming of uncertain optimization results due to artificially specified weights in the existing solution process of the robust optimization model based on hybrid probabilistic and interval variables, and has better engineering practicability.

### BRIEF DESCRIPTION OF THE DRAWINGS

FIG. 1 is a flowchart of a robust optimization design method for a mechanical arm based on hybrid interval and bounded probabilistic uncertainties;

FIG. 2 shows a three-dimensional (3D) model of the mechanical arm; and

FIG. 3 is a design diagram of the mechanical arm.

### DETAILED DESCRIPTION

The present disclosure is described in further detail below with reference to the accompanying drawings and specific embodiments.

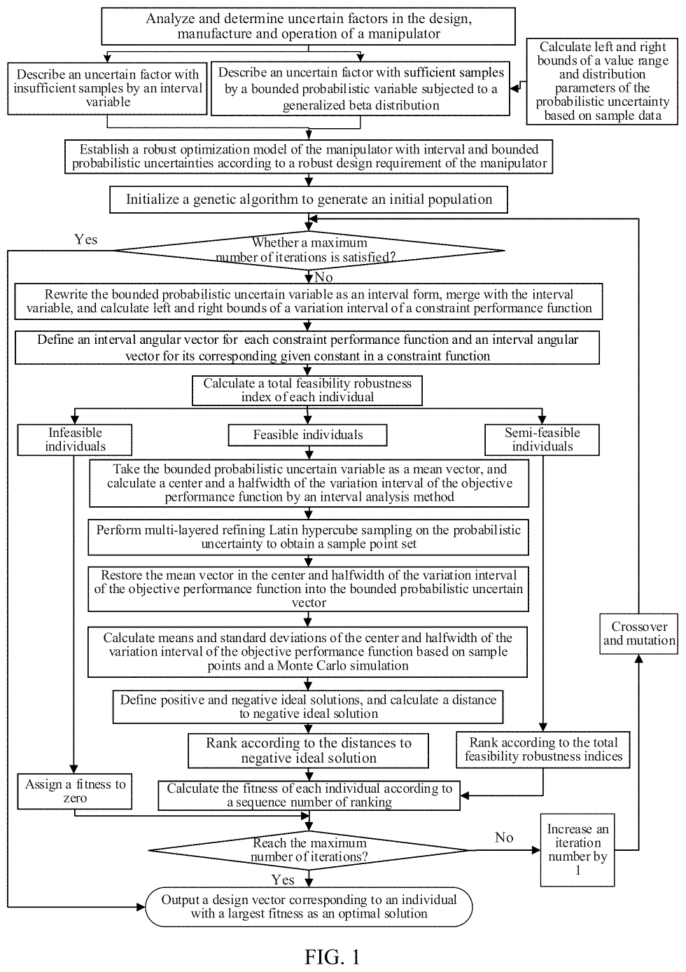

The data involved in the accompanying drawings is the actual application data of the present disclosure in the robust design of a certain type of mechanical arm. FIG. 1 is a flowchart of a robust optimization design method for a mechanical arm based on hybrid interval and bounded probabilistic uncertainties.

1. Uncertainties in a hydraulic cylinder pressure, manufacturing precision and a material property of the mechanical arm are considered and classified into an interval uncertainty and a probabilistic uncertainty, and each probabilistic uncertain parameter is described as a random variable subjected to a generalized beta (GBeta) distribution.

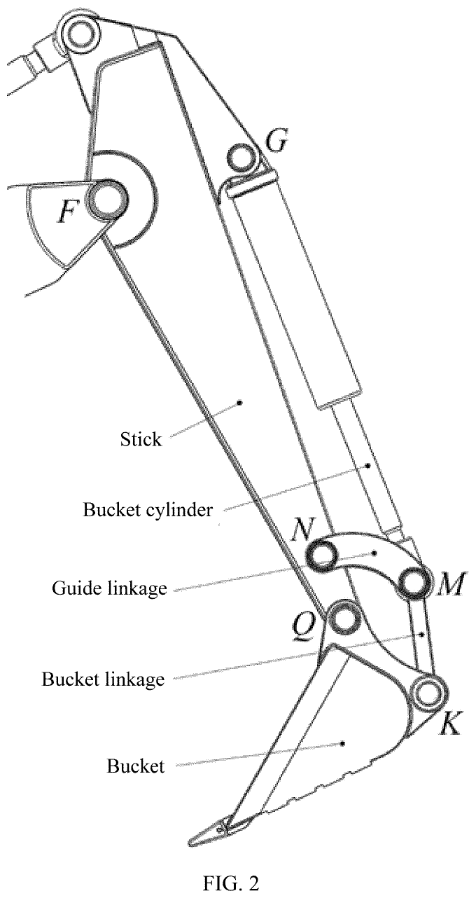

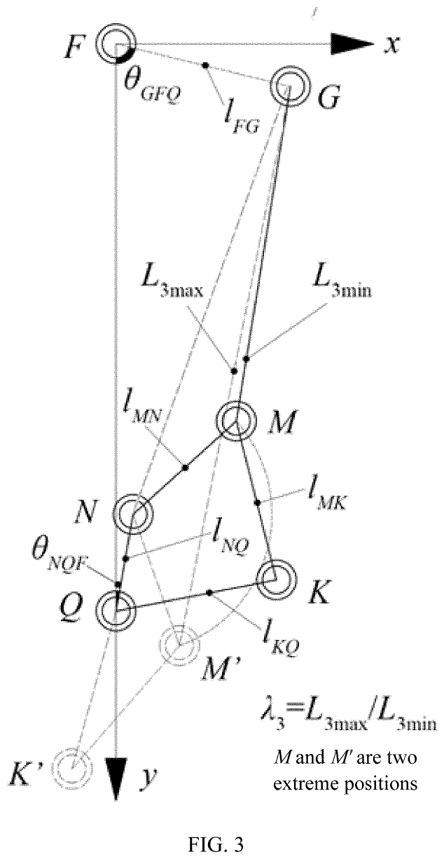

1) Taking the mechanical arm shown in FIGS. 2 and 3 as the research object, considering manufacturing and assembling errors, a forearm length l_{FQ} shown in FIG. 3 is described as an interval variable. A bucket linkage and a guide linkage are made of the same material with relatively low requirement for manufacturing precision, and their density ρ_{linkage} is described as an interval variable due to a lack of sample data. A push rod of a bucket cylinder requires higher manufacturing precision and has enough sample data of density ρ_{pushrod}, so ρ_{pushrod} is described as a bounded probabilistic variable subjected to the GBeta distribution. Meanwhile, considering the uncertain oil supply and sealing capability of the hydraulic system, a cylinder pressure p is described as a bounded probabilistic variable. Sufficient and reliable samples have been collected for the bounded probabilistic variables ρ_{pushrod} and p through experimental measurement, and based on these samples, their means and standard deviations are calculated which are p:μₚ=16.00 MPa, σₚ=0.80 MPa and ρ_{pushrod}:μ_{ρ}=7.68E3 kg/m³, σ_{ρ}=77.00 kg/m³. First, random variables subjected to the GBeta distribution are employed to describe ρ_{pushrod} and p in a bounded form. Taking the probabilistic uncertainty p as an example, the specific operation is as follows:

1.1) Maximum and minimum values of the probabilistic uncertain variable p are selected from the experimental samples by Eq. 1, and they are rounded according to engineering experience. The left and right bounds of the value range are determined as aₚ=15.00 MPa and bₚ=17.00 MPa, and the statistical information of the uncertain variable p is calculated as μₚ=16.00 MPa, σₚ=0.80 MPa.

1.2) The distribution parameters of p are calculated by Eq. 3 and Eq. 4, which are αₚ=βₚ=2.10. Thus p is denoted as a bounded probabilistic variable subjected to a GBeta distribution defined within [1500, 1700] with the distribution parameters αₚ=βₚ=2.10, that is, p˜GBeta(15.00,17.00|2.10,2.10)

Likewise, another bounded probabilistic variable is denoted as ρ_{pushrod}˜GBeta(7.60E3,7.80E3|2.89,4.34). The information of all uncertain variables are summarized in Table 1.

TABLE 1
Information of uncertain variables of the mechanical arm of an excavator

| Uncertain | | | Uncertain |
|---|---|---|---|
| variable | Distribution | Value range | parameter * |
| l_{FQ} (mm) | Interval | [855.00, 865.00] | <860.00, 5.00> |
| p (MPa) | GBeta | [15.00, 17.00] | μ = 16.00, σ = 0.80 |
| | α = β = 2.10 | | |
| ρ_{linkage} (kg/m³) | Interval | [7.25E3, 7.35E3] | <7.30E3, 50.00> |
| ρ_{pushrod} (kg/m³) | GBeta | [7.60E3, 7.80E3] | μ = 7.68E3, |
| | α = 2.89, | | σ = 77.00 |
| | β = 4.34 | | |

* The uncertain parameters of the interval variables are the center and halfwidth of the interval, and the uncertain parameters of the bounded probabilistic variables are the mean and standard deviation.

2. Robust optimization design modeling of the mechanical arm based on the hybrid interval and bounded probabilistic variables:

The parameters of the mechanical arm, including the position coordinates of joints G and N(l_{FG}, θ_{GFQ}, l_{NQ}, θ_{NQF}), the length of the bucket linkage l_{MK}, the length of the guide linkage l_{MN}, the length of a bucket l_{KQ}, the minimum length of the bucket cylinder Lₘᵢₙ and the expansion ratio of the bucket cylinder λ shown in FIG. 3 are selected as design variables, and are listed in Table 2.

TABLE 2
Value ranges of design variables of the mechanical arm in an excavator

| Design | Physical meaning of design | | |
|---|---|---|---|
| variables | variables | Minimum | Maximum |
| l_{FG} (mm) | Distance between points G and F | 225 | 275 |
| θ_{GFQ} (°) | Deflection angle of GF | 60 | 110 |
| l_{NQ} (mm) | Distance between points Nand Q | 110 | 130 |
| θ_{NQF} (°) | Deflection angle of NQ | 5 | 10 |
| l_{MN} (mm) | Length of the guide linkage | 160 | 180 |
| l_{MK} (mm) | Length of the bucket linkage | 185 | 215 |
| l_{KQ} (mm) | Length of a bucket | 185 | 215 |
| Lₘᵢₙ (mm) | Minimum length of the bucket | 560 | 620 |
| | cylinder | | |
| λ | Expansion ratio of the bucket | 1.35 | 1.45 |
| | cylinder | | |

According to the requirements of high-performance and lightweight robust design as well as working conditions of the mechanical arm, a maximum digging moment of the mechanical arm under the influence of the interval and bounded probabilistic uncertainties in an operation process is taken as an objective performance function to be optimized, while a total structural weight of the mechanical arm and a maximum rotation of a bucket which have maximum allowable values are described as constraint performance functions. In this way, a robust optimization design model of the mechanical arm is established based on the hybrid interval and bounded probabilistic variables:

min{−μ_{M}_{^{C}}_{(d,X,U)},σ_{M}_{^{C}}_{(d,X,U)},−μ_{M}_{^{W}}_{(d,X,U)},σ_{M}_{^{W}}_{(d,X,U)}}

s.t.[W_{Total}^{L*}(d,X,U),W_{Total}^{R*}(d,X,U)]≤[100.6,101.0] kg

[−φ^{R*}(d,X,U),−φ^{L*}(d,X,U)]≤[−95°,−90°]

[gᵢ^{L*}(d,X,U),gᵢ^{R*}(d,X,U)]≤0 (i=1,2,3,4)

g₁(d,X,U)=Lₘᵢₙ−(l_{GN}(d,X,U)+l_{MN})

g₂(d,X,U)=Lₘᵢₙ·λₘᵢₙ−(l_{GN}(d,X,U)+l_{MN})

g₃(d,X,U)=l_{GN}(d,X,U)−(Lₘᵢₙ+l_{MN})

g₄(d,X,U)=l_{GN}−(Lₘᵢₙ·λ+l_{MN})

d=(l_{FG},θ_{GFQ},l_{NQ},θ_{NQF},l_{MN},l_{MK},l_{KQ},Lₘᵢₙ,λ)

X=(p,ρ_{pushrod}),U=(l_{FQ},ρ_{linkage}),

where d=(l_{FG}, θ_{GFQ}, l_{NQ}, θ_{NQF}, l_{MN}, l_{MK}, l_{KQ}, Lₘᵢₙ, λ) is a design vector; X=(p, ρ_{pushrod}) is a bounded probabilistic uncertain vector; U=(l_{FQ}, ρ_{linkage}) is an interval uncertain vector; l_{GN}(d, X, U) is a distance between joints G and N, which can be obtained by solving a triangle; μ_{M}_{^{C}}_{(d,X,U)}, σ_{M}_{^{C}}_{(d,X,U)}, μ_{M}_{^{W}}_{(d,X,U)} and σ_{M}^{W}_{(d,X,U)} respectively are a mean and a standard deviation of a center, and a mean and a standard deviation of a halfwidth in a variation interval of an objective performance function M(d, X, U) under the influence of the bounded probabilistic uncertain vector X and the interval uncertain vector U. A minus sign is added before μ_{M}_{^{C}}_{(d,X,U)} and μ_{M}_{^{W}}_{(d,X,U)}, so as to convert the problem of maximization into a standard minimization problem. The objective performance function M(d, X, U) denotes a maximum digging moment in the operation process of the mechanical arm, whose analytical expression can be derived by an analytical method. μ_{M}_{^{C}}_{(d,X,U)}, σ_{M}_{^{C}}_{(d,X,U)}, μ_{M}_{^{W}}_{(d,X,U)} and σ_{M}_{^{W}}_{(d,X,U)} are as calculated as follows:

2.1) The bounded probabilistic uncertain vector X=(p, ρ_{pushrod}) in the objective performance function M(d, X, U) is substituted with a mean vector μ_{X}=(μₚ, μ_{ρ}_{_{pushrod}}) to transform the objective performance function into a function M(d, μ_{X}, U), which includes only the interval uncertain vector U=(l_{FQ}, ρ_{linkage}) and whose value is an interval number;

2.2) An interval analysis of M(d, μ_{X}, U) is conducted to obtain upper and lower bounds M^{L}(d, μ_{X}) and M^{R}(d, μ_{X}) of the variation interval of the objective performance function M(d, μ_{X}, U) at the mean vector μ_{X};

2.3) The center M^{C}(d, μ_{X}) and halfwidth M^{W}(d, μ_{X}) of the variation interval of the objective performance function M(d, μ_{X}, U) at the mean vector μ_{X} are further calculated, where M^{L}(d, μ_{X}), M^{R}(d, μ_{X}), M^{C}(d, μ_{X}) and M^{W}(d, μ_{X}) have no uncertainty and each has a real-number value;

2.4) The mean vector μ_{X} in M^{C}(d, μ_{X}) and M^{W}(d, μ_{X}) is restored to the bounded probabilistic uncertain vector X. Multi-layered refining Latin hypercube sampling (MRLHS) is conducted within a probabilistic distribution range of the bounded probabilistic uncertain vector X. A value of the objective performance function corresponding to each sample point is calculated, where the objective performance function of each sample point has no uncertainty and has a real-number value. Then a Monte Carlo approach is employed to calculate the mean μ_{M}_{^{C}}_{(d,X,U)} and standard deviation σ_{M}_{^{C}}_{(d,X,U)} of the center and the mean μ_{M}_{^{W}}_{(d,X,U)} and standard deviation σ_{M}_{^{W}}_{(d,X,U)} of the halfwidth in the variation interval of the objective performance function M(d, X, U) under the influence of the bounded probabilistic uncertain vector X and the interval uncertain vector U;

In the robust optimization design model of the mechanical arm, W_{Total}^{L*}(d, X, U) and W_{Total}^{R*}(d, X, U) are left and right bounds of a variation interval of the total structural weight W_{Total}(d, X, U) under the influence of the hybrid interval and bounded probabilistic uncertainties. φ^{L*}(d, X, U), φ^{R*}(d, X, U) are left and right bounds of a variation interval of the maximum rotation φ(d, X, U), 100 ^{R*}(d, X, U) under the influence of the hybrid interval and bounded probabilistic uncertainties. Since φ(d, X, U) is originally defined to be no less than a given value, a minus sign is added to unify the expression of the constraint performance function into a form of not exceeding the given value. W_{Total}^{L*}(d, X, U), W_{Total}^{R*}(d, X, U), φ^{L*}(d, X, U) and φ^{R*}(d, X, U) are all calculated based on the boundedness of the hybrid bounded probabilistic and interval uncertainties. For example, W_{Total}^{L*}(d, X, U) and W_{Total}^{R*}(d, X, U) are calculated as follows:

2.5) The probabilistic uncertain vector X is rewritten as an interval form X^{I}=(p^{I}, ρ_{pushrod}^{I}) by the boundedness, where p^{I}=[aₚ, bₚ] and ρ_{pushrod}^{I}=[a_{ρ}_{_{pushrod}}, b_{ρ}_{_{pushrod}}] respectively are an interval number corresponding to the bounded probabilistic uncertain variables p and ρ_{pushrod}; I is a mark of an interval representation form corresponding to the bounded probabilistic uncertainty;

2.6) The interval vector U and the interval representation form X^{I} of the bounded probabilistic uncertain vector are merged into a new interval uncertain vector, denoted as H_{U}^{X}^{^{I}}=(X^{I}, U). Then, W_{Total}^{L*}(d, X, U) and W_{Total}^{R*}(d, X, U) are calculated as follows:

$$\{ \begin{matrix}{W}_{Total}^{{L}^{*}} ( d , X , U ) = {min}_{{H}_{U}^{{X}^{I}}} {W}_{Total} ( d , {H}_{U}^{{X}^{I}} ) \\ {W}_{Total}^{{R}^{*}} ( d , X , U ) = {max}_{{H}_{U}^{{X}^{I}}} {W}_{Total} ( d , {H}_{U}^{{X}^{I}} )\end{matrix} .$$

In the robust optimization design model of the mechanical arm, gᵢ^{L*}(d, X ,U), gᵢ^{R*}(d, X ,U) (i=1, 2, 3, 4) are left and right bounds of the performance variation interval of the geometric constraint function gᵢ(d, X, U) (i=1, 2, 3, 4) under the influence of the hybrid interval and bounded probabilistic uncertainties.

3. The robust optimization design model of the mechanical arm is directly solved based on a genetic algorithm (GA), a total feasibility robustness index and a distance to negative ideal solution (DNIS):

3.1) GA parameters are set as follows: maximum number of iterations 150, population size 200, crossover probability 0.99, mutation probability 0.02 and convergent threshold 1E-5. A current iteration number of the GA is set to 1, and an initial population of the GA is generated as:

d₁=(228.024,67.972,117.406,10.673,173.740,192.364,200.362,600.760,1.384),

d₂=(232.486,75.531,120.941,8.975,170.156,200.543,197.799,589.007,1.408) . . .

d₂₀₀=(221.804,72.912,118.150,8.503,185.726,203.714,195.065,593.330,1.419).

The direct solution process of the robust optimization design model of the mechanical arm based on the GA is illustrated below take the 1st iteration process as an example.

3.2) Robustness of the constraint performance functions of each individual in the current population is assessed, and for an individual corresponding to the design vector d , the specific robustness is assessed as follows:

3.2.1) According to steps 2.5) and 2.6), the left and right bounds of the performance variation intervals of the total weight constraint function W_{Total}(d, X, U), the maximum rotation constraint function φ(d, X, U) and the four geometric constraint functions gᵢ(d, X, U) (i=1, 2, 3, 4) of the mechanical arm of all individuals in the current population are calculated (for the sake of brevity, only the left and right bounds of the performance variation intervals of W_{Total}(d, X, U) and φ(d, X ,U) of some individuals are presented here):

d₁(d, X, U)=100.195 kg. W_{Total}^{R*}(d, X, U)=100.767 kg; φ^{L*}(d, X, U)=94.998°, φ^{R*}(d, X, U)=97.130°; d₂(W_{Total}^{L*}(d, X, U)=110.108 kg, W_{Total}^{R*}(d, X, U)=110.534 kg; φ^{L*}(d, X, U)=99.015°, φ^{R*}(d, X, U)=100.074°) . . . d₂₀₀(W_{Total}^{L*}(d, X, U)=103.156 kg, W_{Total}^{R*}(d, X ,U)=103.701 kg; φ^{L*}(d, X, U)=96.541°, φ^{R*}(d, X, U)=98.700°).

For each constraint performance function (six in total), the corresponding interval angular vectors a_{G}_{ᵢ}_{^{S}} and a_{B}_{ᵢ} of all individuals in the current population can be defined.

3.2.2) A feasibility robustness index of every corresponding constraint performance function of each individual is calculated by Eq. 15.

3.2.3) A total feasibility robustness index S of all corresponding constraint performance functions of each individual is calculated by Eq. 17: S₁=2, S₂=1.430, S₃=2, S₄=1.178, S₅=0, S₆=1.016 . . . S₁₉₈=0, S₁₉₉=1.370, S₂₀₀=1.512.

3.3) According to the total feasibility robustness index S, all the individuals in the current population are classified as (a) feasible if S=p, (b) semi-feasible if 0<S<p, and (c) infeasible if S=⁰. The feasible individuals include d₁, d₃, etc. (37 in total); the semi-feasible individuals include d₂, d₄, d₆, d₁₉₉, d200, etc. (98 in total); the infeasible individuals include d₅, d₁₉₈, etc. (65 in total).

3.4) The means and standard deviations of the corresponding objective performance function of the 37 feasible individuals are calculated through the MRLHS-based Monte Carlo approach according to steps 2.1) to 2.4), where the MRLHS-based Monte Carlo approach specifically includes the following steps:

3.4.1) A 2-dimensional sampling domain D²=[15.00,17.00]×[7.6E3,7.8E3] is determined.

3.4.2) Demarcation points are determined as follows:

$$\{ \begin{matrix}δ {p}^{L} = {F}_{p}^{- 1} ( 0.3 , 2.10 , 2.10 ) \\ δ {p}^{R} = {F}_{p}^{- 1} ( 0.7 , 2.10 , 2.10 ) \\ {p}_{t}^{L} = {F}_{p}^{- 1} ( 0.2 , 2.10 , 2.10 ) \\ {p}_{t}^{R} = {F}_{p}^{- 1} ( 0.8 , 2.10 , 2.10 )\end{matrix} \\ \{ \begin{matrix}δ {ρ}_{p u s h r o d}^{L} = {F}_{{ρ}_{pushrod}}^{- 1} ( 0.3 , 2.89 , 4.34 ) \\ δ {ρ}_{p u s h r o d}^{R} = {F}_{{ρ}_{pushrod}}^{- 1} ( 0.7 , 2.89 , 4.34 ) \\ {ρ}_{p u s h r o d t}^{L} = {F}_{{ρ}_{pushrod}}^{- 1} ( 0.2 , 2.89 , 4.34 ) \\ {ρ}_{p u s h r o d t}^{R} = {F}_{{ρ}_{pushrod}}^{- 1} ( 0.8 , 2.89 , 4.34 )\end{matrix} .$$

The sampling domain is extracted and divided into three layers, namely the original sampling domain D², a mean neighborhood δD_{μ}² and a transitional layer Dₜᵣₐₙ²:

δD_{μ}²=[δp^{L},δp^{R}]×[δρ_{pushrod}^{L},δρ_{pushrod}^{R}], and

Dₜᵣₐₙ²=[pₜ^{L},pₜ^{R}]×[ρ_{pushrodt}^{L},ρ_{pushrodt}^{R}].

3.4.3) Assuming that a total sample size is 3E4, then standard Latin hypercube sampling (LHS) is conducted with a size of 1E4 in every layer, and the sample points in each layer are superimposed to obtain a final sample point set.

3.4.4) Based on the obtained final sample point set, Monte Carlo simulations are conducted for the feasible individuals in the population, to obtain the means and standard deviations of the center and the means and standard deviations of the halfwidth in the variation intervals of the objective performance function M(d, X ,U) under the influence of the bounded probabilistic uncertain vector X and the interval uncertain vector U. Taking the mean μ_{M}_{^{C}}_{(d,X,U)} and the standard deviation σ_{M}_{^{C}}_{(d,X,U)} of the center in the variation interval of the objective performance function M(d, X, U) as an example, they are calculated as follows:

$${μ}_{{M}^{C} ( d , X , U )} \approx \frac{1}{N} {\sum }_{k = 1}^{N} {M}^{C} ( d , {X}_{k} ) , and$$

$${σ}_{{M}^{C} ( d , X , U )} \approx \sqrt{\frac{1}{N - 1} {\sum }_{k = 1}^{N} {[ {M}^{C} ( d , {X}_{k} ) - {μ}_{{M}^{C} ( d , X , U )} ]}^{2}} .$$

3.5) According to a classification result of the individuals in the current population in step 3.3) and a calculation result of the means and standard deviations of the center and halfwidth in the variation intervals of the objective performance function of the feasible individuals in step 3.4), all individuals in the population are ranked based on the distances to negative ideal solution (DNIS_{S}). Specifically:

3.5.1) The 37 feasible individuals are compared to define positive and negative ideal solutions (PIS, NIS): μₘₐₓ^{C}=2206.132 kNm, μₘᵢₙ^{C}=1978.061 kNm, σₘₐₓ^{C}68.414 kNm, σₘᵢₙ^{C}=61.016 kNm, μₘₐₓ^{W}=30.021 kNm, μₘᵢₙ^{W}26.592 kNm, σₘₐₓ^{W}=7.427E−2 kNm, σₘᵢₙ^{W}=9.828E−2 kNm. Then, the DNIS of each feasible individual is calculated, that is, D*(d₁)=0.1292, D*(d₃)=0.1311, etc.

3.5.2) The feasible individuals and the semi-feasible individuals are ranked, so that each individual participating in the ranking obtains a unique sequence number and an individual with inferior objective or constraint robustness has a larger sequence number. Specifically:

a) The 37 feasible individuals are ranked in a descending order of the DNIS D*(d) from largest to smallest, so that each feasible individual obtains a unique sequence number.

b) The 98 semi-feasible individuals are ranked in a descending order of the total feasibility robustness index S from largest to smallest, where a smaller S indicates that the corresponding semi-feasible individual has inferior robustness in the constraint performance function and has a larger sequence number. When the feasible individuals and the semi-feasible individuals are ranked, the sequence number of the 1st semi-feasible individual closely follows the sequence number of the 37th feasible individual. The sequence numbers of the two types of individuals are continuous, and the sequence numbers of the semi-feasible individuals are greater than those of the feasible individuals. Likewise, each semi-feasible individual obtains a unique sequence number.

3.5.3) All the individuals are assigned a fitness value, where the fitness values of the feasible and semi-feasible individuals are the reciprocals of their sequence numbers obtained by ranking, and the fitness values of the infeasible individuals are directly assigned as 0.

3.6) It is determined that neither the maximum number of iterations 150 or the convergent threshold 0.00001 is satisfied. Thus, crossover and mutation operations are conducted on the individuals in the current population to generate a new population of 200 individuals. The iteration number is increased by 1, and the 2nd iteration is started.

Steps 3.2) to 3.6) are implemented for the individuals in each generation of population until the maximum number of iterations or the convergent threshold is satisfied. A final optimization result is achieved when the objective performance index reaches the convergent threshold at the 32nd iteration, and the optimal design vector corresponding to an individual with the largest fitness is:

d⁰=(231.864,65.900,120.310,10.156,173.508,192.865,202.436,601.612,1.398).

The maximum digging moment of the mechanical arm corresponding to the optimal design vector is (μ_{M}_{^{C}}, σ_{M}_{^{C}}, μ_{M}_{^{W}}, σ_{M}_{^{W}})=(2048.635, 68.301, 59.6823, 1.864E−1) kNm; the total weight of the mechanical arm corresponding to the optimal design vector is (W_{Total}^{L*}, W_{Total}^{R*})=(100.059, 100.415) kg; the maximum bucket rotation is (φ^{L*}, φ^{R*})=(94.989°, 97.098°). They all meet the high-performance and lightweight robust design requirements and working conditions for the mechanical arm, thereby verifying the effectiveness of the proposed method.

It should be noted that the content and specific implementations of the present disclosure are intended to illustrate the practical application of the technical solutions provided by the present disclosure, rather than to limit the protection scope of the present disclosure. Any modifications and changes made to the present disclosure within the spirit and the protection scope of the claims of the present disclosure should fall into the protection scope of the present disclosure.

What is claimed is:

1. A robust optimization design method for a mechanical arm based on hybrid interval and bounded probabilistic uncertainties, comprising following steps:
1) considering uncertainties in a hydraulic cylinder pressure, manufacturing precision and a material property of the mechanical arm and classifying them into an interval uncertainty and a bounded probabilistic uncertainty, and describing each bounded probabilistic uncertain parameter as a random variable subjected to a generalized beta (GBeta) distribution:
1.1) obtaining, for a bounded probabilistic uncertain variable Xᵢ, s samples through an experiment to construct a sample point set {Xᵢ¹, Xᵢ², . . . , Xᵢ^{s}}; calculating, based on the sample point set, a value range of the variable Xᵢ by Eq. 1, and calculating a mean and a variance of the variable Xᵢ by Eq. 2:
$$\begin{matrix}\{ \begin{matrix}{a}_{i} = min \{ {X}_{i}^{1} , {X}_{i}^{2} , … , {X}_{i}^{s} \} \\ {b}_{i} = max \{ {X}_{i}^{1} , {X}_{i}^{2} , … , {X}_{i}^{s} \}\end{matrix} , and & Eq . 1 \\ \{ \begin{matrix}{μ}_{{X}_{i}} = \frac{1}{s} {\sum }_{k = 1}^{s} {X}_{i}^{k} \\ {S}_{{X}_{i}}^{2} = \frac{1}{s} {\sum }_{k = 1}^{s} {( {X}_{i}^{k} - {μ}_{{X}_{i}} )}^{2} ;\end{matrix} & Eq . 2\end{matrix}$$
1.2) describing, by the GBeta distribution, the variable Xᵢ that is distributed within [aᵢ, bᵢ] and has a mean of μ_{X,} and a variance of S_{X}_{ⁱ}²; firstly, normalizing the mean and the variance of the variable Xᵢ by Eq. 3:
$$\{ \begin{matrix}{\hat{μ}}_{{X}_{i}} = \frac{{μ}_{{X}_{i}} - {a}_{i}}{{b}_{i} - {a}_{i}} \\ {\hat{S}}_{{X}_{i}}^{2} = \frac{{S}_{{X}_{i}}^{2}}{{( {b}_{i} - {a}_{i} )}^{2}}\end{matrix} , \qquad Eq . 3$$
then, calculating distribution parameters αᵢ and βᵢ of the GBeta distribution of the variable Xᵢ by Eq. 4:
$$\{ \begin{matrix}{α}_{i} = \frac{1 - {\hat{μ}}_{{X}_{i}}}{1 + {\hat{μ}}_{{X}_{i}}} \cdot \frac{1}{{\hat{S}}_{{X}_{i}}^{2}} \\ {β}_{i} = \frac{{( 1 - {\hat{μ}}_{{X}_{i}} )}^{2}}{{\hat{μ}}_{{X}_{i}} ( 1 + {\hat{μ}}_{{X}_{i}} )} \cdot \frac{1}{{\hat{S}}_{{X}_{i}}^{2}}\end{matrix} , \qquad Eq . 4$$
denoting the variable Xᵢ subjected to the GBeta distribution within [aᵢ, bᵢ] with the distribution parameters αᵢ and βᵢ as Xᵢ˜GBeta(aᵢ, bᵢ|αᵢ, βᵢ), wherein a probabilistic density function of the variable Xᵢ is defined by Eq. 5:
$${f}_{{X}_{i}} ( {X}_{i} ; {α}_{i} , {β}_{i} \vert {a}_{i} , {b}_{i} ) = \frac{Γ ( {α}_{i} + {β}_{i} )}{Γ ( {α}_{i} ) Γ ( {β}_{i} )} {( \frac{1}{{b}_{i} - {a}_{i}} )}^{{α}_{i} + {β}_{i} - 1} \cdot {( {X}_{i} - {a}_{i} )}^{{α}_{i} - 1} {( {b}_{i} - {X}_{i} )}^{{β}_{i} - 1} , \qquad Eq . 5$$
wherein in Eq. 5, ƒ_{X}_{ᵢ}(⋅) is the probabilistic density function of the variable Xᵢ, and Γ(⋅) is a gamma function;
2) establishing a robust optimization design model of the mechanical arm with the hybrid interval and bounded probabilistic uncertainties by taking a maximum loading capacity of the mechanical arm in operation under an influence of the hybrid interval and bounded probabilistic uncertainties as an optimization objective, and describing a performance index of the mechanical arm with a given maximum allowable value as a constraint performance function, the robust optimization design model being shown in Eq. 6:
$${min}_{d} \{ {μ}_{{f}^{C} ( d , X , U )} , {σ}_{{f}^{C} ( d , X , U )} , {μ}_{{f}^{W} ( d , X , U )} , {σ}_{{f}^{W} ( d , X , U )} \} \\ s . t . [ {g}_{i}^{{L}^{*} ( d , X , U )} , {g}_{i}^{{R}^{*}} ( d , X , U ) ] \leq {B}_{i} = [ {b}_{i}^{L} , {b}_{i}^{R} ] , \\ i = 1 , 2 , … , p \\ d = ( {d}_{1} , {d}_{2} , … , {d}_{i} ) , \\ X = ( {X}_{1} , {X}_{2} , … , {X}_{m} ) , \\ U = ( {U}_{1} , {U}_{2} , … , {U}_{n} ) , \qquad Eq . 6$$
wherein in Eq. 6, d=(d₁, d₂, . . . , dₗ) is an l-dimensional design vector; X=(X₁, X₂, . . . , Xₘ) is an m-dimensional bounded probabilistic uncertain vector; U=(U₁, U₂, . . . , Uₙ) is an n-dimensional interval uncertain vector; Bᵢ is an interval constant given based on a design requirement; bᵢ^{L} and bᵢ^{R} are left and right bounds of Bᵢ respectively, and when bᵢ^{L}=bᵢ^{R}, the interval constant Bᵢ degenerates to a real number; p is a number of constraint performance functions; gᵢ^{L*}(d, X, U) and gᵢ^{R*}(d, X, U) are respectively left and right bounds of a performance variation interval of an i-th constraint performance function gᵢ(d, X, U) under the influence of the hybrid interval and bounded probabilistic uncertainties, and gᵢ^{L*}(d, X, U) and gᵢ^{R*}(d, X, U) are calculated as follows:
a) rewriting the probabilistic uncertain vector X as an interval form X^{I}=(X₁^{I}, X₂^{I}, . . . , Xₘ^{I}) utilizing boundedness of the probabilistic uncertain vector X, wherein Xᵢ^{I}=[aᵢ, bᵢ] (i=1, 2, . . . , m) is an interval number corresponding to the bounded probabilistic uncertain variable Xᵢ; aᵢ, bᵢ are determined by Eq. 1; I is a mark of an interval representation form corresponding to the bounded probabilistic uncertain variable;
b) merging the interval vector U and the interval form X^{I} of the bounded probabilistic uncertain vector into a new interval uncertain vector H_{U}^{X}^{^{I}}=(X^{I}, U), and calculating gᵢ^{L*}(d, X, U) and gᵢ^{R*}(d, X, U) with Eq. 7:
$$\{ \begin{matrix}{g}_{i}^{{L}^{*}} ( d , X , U ) = {min}_{{H}_{U}^{{X}^{I}}} {g}_{i} ( d , {H}_{U}^{{X}^{I}} ) \\ {g}_{i}^{{R}^{*}} ( d , X , U ) = {max}_{{H}_{U}^{{X}^{I}}} {g}_{i} ( d , {H}_{U}^{{X}^{I}} )\end{matrix} \\ ( i = 1 , 2 , … , p ) , \qquad Eq . 7$$
wherein in Eq. 6, μ_{ƒ}_{^{C}}_{(d,X,U)}, σ_{ƒ}_{^{C}}_{(d,X,U)}, μ_{ƒ}_{^{W}}_{(d,X,U)}, σ_{ƒ}_{^{W}}_{(d,X,U)} are respectively a mean and a standard deviation of a center, and a mean and a standard deviation of a halfwidth of a variation interval of an objective performance function ƒ(d, X, U) under the influence of the bounded probabilistic uncertain vector X and the interval uncertain vector U, which are calculated as follows:
A) defining μ_{X}=(μ_{X}_{₁}, μ_{X}_{₂}, . . . , μ_{X}_{ₘ}) as a constant vector obtained by taking a mean of each probabilistic variable in the bounded probabilistic uncertain vector X, and denoting μ_{X} as a mean vector of the bounded probabilistic uncertain vector X; substituting the bounded probabilistic uncertain vector X in the objective performance function ƒ(d, X, U) with the mean vector μ_{X} to transform the objective performance function into a function ƒ(d, μ_{X}, U), which comprises only the interval uncertain vector U and whose value is an interval number;
B) performing an interval analysis of ƒ(d, μ_{X}, U) through an interval analysis algorithm by Eq. 8 to obtain left and right bounds ƒ^{L}(d, μ_{X}) and ƒ^{R}(d, μ_{X}) of a variation interval of the objective performance function ƒ(d, μ_{X}, U) at the mean vector μ_{X}:
$$\{ \begin{matrix}{f}^{L} ( d , {μ}_{X} ) = {f}^{L} ( d , {μ}_{X} , U ) {\vert}_{U = {U}_{min}^{*}} = {min}_{U} f ( d , {μ}_{X} , U ) \\ {f}^{R} ( d , {μ}_{X} ) = {f}^{R} ( d , {μ}_{X} , U ) {\vert}_{U = {U}_{max}^{*}} = {max}_{U} f ( d , {μ}_{X} , U )\end{matrix} , \qquad Eq . 8$$
wherein in Eq. 8, U*ₘᵢₙ and U*ₘₐₓ are interval uncertain vectors to minimize and maximize ƒ(d, μ_{X}, U), respectively;
C) calculating, by Eq. 9, a center ƒ^{C}(d, μ_{X}) and a halfwidth ƒ^{W}(d, μ_{X}) of the variation interval of the objective performance function ƒ(d, μ_{X}, U) at the mean vector μ_{X}:
$$\{ \begin{matrix}{f}^{C} ( d , {μ}_{X} ) = ( {f}^{L} ( d , {μ}_{X} ) + {f}^{R} ( d , {μ}_{X} ) ) / 2 \\ {f}^{W} ( d , {μ}_{X} ) = ( {f}^{R} ( d , {μ}_{X} ) - {f}^{L} ( d , {μ}_{X} ) ) / 2\end{matrix} , \qquad Eq . 9$$
wherein in Eq. 9, ƒ^{L}(d, μ_{X}), ƒ^{R}(d, μ_{X}), ƒ^{C}(d, μ_{X}) and ƒ^{W}(d, μ_{X}) have no uncertain variable and each has a real-number value;
D) restoring μ_{X} in ƒ^{C}(d, μ_{X}) and ƒ^{W}(d, μ_{X}) to the bounded probabilistic uncertain vector X; performing multi-layered refining Latin hypercube sampling (MRLHS) within a probabilistic distribution range of the bounded probabilistic uncertain vector X; calculating a value of the objective performance function corresponding to each sample point, wherein the objective performance function corresponding to each sample point has no uncertainty and has a real-number value; calculating, by a Monte Carlo approach, the mean μ_{ƒ}_{^{C}}_{(d,X,U)} and standard deviation σ_{ƒ}_{^{C}}_{(d,X,U)} of the center and the mean μ_{ƒ}_{^{W}}_{(d,X,U)} and standard deviation σ_{ƒ}_{^{W}}_{(d,X,U)} of the halfwidth in the variation interval of the objective performance function ƒ(d, X, U) under the influence of the bounded probabilistic uncertain vector X and the interval uncertain vector U, specifically as follows:
D.1) determining an m-dimensional original sampling domain D^{m}=[a₁,b₁]×[a₂, b₂]× . . . ×[aₘ, bₘ], where aᵢ, bᵢ (i=1, 2, . . . , m) are boundary values of the bounded probabilistic uncertain variable Xᵢ determined by Eq. 1, and × is a Cartesian product operator in a linear space;
D.2) constructing, by dividing and extracting the original sampling domain D^{m}, a mean neighborhood layer sampling domain δD_{μ}^{m} and a transitional layer sampling domain Dₜᵣₐₙ^{m} to form three layers of sampling domains, namely D^{m}, δD_{μ}^{m} and Dₜᵣₐₙ^{m}:
δD_{μ}^{m}[δX₁^{L},δX₁^{R}]×[δX₂^{L},δX₂^{R}]× . . . ×[δXₘ^{L},δXₘ^{R}] Eq. 10, and
Dₜᵣₐₙ^{m}[X₁ₜ^{L},X₁ₜ^{R}]×[X₂ₜ^{L},X₂ₜ^{R}]× . . . ×[Xₘₜ^{L},Xₘₜ^{R}] Eq. 11,
wherein in Eq. 10 and Eq. 11, δXᵢ^{L} and δXᵢ^{R} (i=1, 2, . . . , m) are left and right bounds of an i-th dimension in the m-dimensional mean neighborhood layer sampling domain δD_{μ}^{m} respectively; Xᵢₜ^{L} and Xᵢₜ^{R} (i==1, 2, . . . , m) are left and right bounds of the i-th dimension in the m-dimensional transitional layer sampling domain Dₜᵣₐₙ^{m} respectively; the left and right bounds are determined by Eq. 12:
$$\{ \begin{matrix}δ {X}_{i}^{L} = {F}_{{X}_{i}}^{- 1} ( 0.3 , {α}_{i} , {β}_{i} ) \\ δ {X}_{i}^{R} = {F}_{{X}_{i}}^{- 1} ( 0.7 , {α}_{i} , {β}_{i} ) \\ {X}_{it}^{L} = {F}_{{X}_{i}}^{- 1} ( 0.2 , {α}_{i} , {β}_{i} ) \\ {X}_{it}^{R} = {F}_{{X}_{i}}^{- 1} ( 0.8 , {α}_{i} , {β}_{i} )\end{matrix} ( i = 1 , 2 , … , m ) , \qquad Eq . 12$$
wherein in Eq. 12, F_{X}_{ᵢ}⁻¹(⋅) is an inverse function of a probabilistic cumulative function F_{X}_{ᵢ}(⋅) of the bounded probabilistic uncertain variable Xᵢ;
D.3) setting a total sample size to N, performing standard Latin hypercube sampling (LHS) with a size of N/3 in each of the three layers of sampling domains, and superimposing sample points of each layer to obtain a final sample point set;
D.4) calculating, by the Monte Carlo approach based on the obtained final sample point set, the mean μ_{ƒ}_{^{C}}_{(d,X,U)} and standard deviation σ_{ƒ}_{^{C}}_{(d,X,U)} of the center and the mean μ_{ƒ}_{^{W}}_{(d,X,U)} and standard deviation σ_{ƒ}_{^{W}}_{(d,X,U)} of the halfwidth in the variation interval of the objective performance function ƒ(d, X, U) under the influence of the bounded probabilistic uncertain vector X and the interval uncertain vector U; and
3) directly solving the robust optimization design model of the mechanical arm based on a genetic algorithm (GA), a total feasibility robustness index and a distance to negative ideal solution (DNIS):
3.1) setting GA parameters, comprising population size, maximum number of iterations, mutation and crossover probabilities, and convergence criterion; setting a current iteration number of the GA to 1, and generating an initial population of the GA;
3.2) performing robustness assessment for a constraint performance function of each individual in a current population, and calculating a total feasibility robustness index S corresponding to a design vector d;
3.3) classifying all the individuals in the current population according to the total feasibility robustness index S and marking an individual as (a) feasible if S=p, (b) semi-feasible if 0<S<p, and (c) infeasible if S=0;
3.4) calculating a mean and a standard deviation of an objective function corresponding to a feasible individual by an MRLHS-based Monte Carlo approach according to steps D.1) to D.4);
3.5) ranking, according to a classification result of the individuals in the current population in step 3.3) and a calculation result of the means and standard deviations of the objective function of the feasible individuals in step 3.4), all individuals in the population based on the total feasibility robustness indices and the DNIS_{S} to obtain a fitness of each individual in the current population;
3.6) determining whether the maximum number of iterations or the convergence criterion is satisfied; if yes, outputting a design vector corresponding to an individual with a largest fitness as an optimal solution; if not, performing crossover and mutation operations, increasing the iteration number by 1 to produce a new generation of population individuals, and returning to step 3.2).

2. The robust optimization design method for the mechanical arm based on the hybrid interval and bounded probabilistic uncertainties according to claim 1, wherein in step D.4), the mean μ_{ƒ}_{^{C}}_{(d,X,U)} and the standard deviation σ_{ƒ}_{^{C}}_{(d,X,U)} of the center of the variation interval of the objective performance function ƒ(d, X, U) are calculated by Eq. 13:
$$\{ \begin{matrix}{μ}_{{f}^{C} ( d , X , U )} \approx \frac{1}{N} {\sum }_{k = 1}^{N} {f}^{C} ( d , {X}_{k} ) \\ {σ}_{{f}^{C} ( d , X , U )} \approx \sqrt{\frac{1}{N - 1} {\sum }_{k = 1}^{N} {[ {f}^{C} ( d , {X}_{k} ) - {μ}_{{f}^{C} ( d , X , U )} ]}^{2}}\end{matrix} , \qquad Eq . 13$$
wherein in Eq. 13, N is the total sample size, and Xₖ (k=1, 2, . . . , N) is a k-th sample point in the final sample point set; and
the mean μ_{ƒ}_{^{W}}_{(d,X,U)} and the standard deviation σ_{ƒ}_{^{W}}_{(d,X,U)} of the halfwidth of the variation interval of the objective performance function ƒ(d, X, U) are calculated by Eq. 14:
$$\{ \begin{matrix}{μ}_{{f}^{W} ( d , X , U )} \approx \frac{1}{N} {\sum }_{k = 1}^{N} {f}^{W} ( d , {X}_{k} ) \\ {σ}_{{f}^{W} ( d , X , U )} \approx \sqrt{\frac{1}{N - 1} {\sum }_{k = 1}^{N} {[ {f}^{W} ( d , {X}_{k} ) - {μ}_{{f}^{W} ( d , X , U )} ]}^{2}}\end{matrix} . \qquad Eq . 14$$

3. The robust optimization design method for the mechanical arm based on the hybrid interval and bounded probabilistic uncertainties according to claim 1, wherein step 3.2) specifically comprises:
3.2.1) denoting Gᵢ^{CS}=(gᵢ^{L*}(d, X, U)+gᵢ^{R*}(d, X, U))/2 and Gᵢ^{WS}=(gᵢ^{R*}(d, X, U)−gᵢ^{L*}(d, X, U))/2 as a center and a halfwidth in a variation interval of the i-th constraint performance function gᵢ(d, X, U), and defining an interval angular vector of the constraint performance function gᵢ(d, X, U) as a_{G}_{ᵢ}_{^{S}}=(Gᵢ^{CS}, Gᵢ^{WS}), with a norm of ∥a_{G}_{ᵢ}_{^{S}}∥; denoting Bᵢ^{C}=(bᵢ^{L}+bᵢ^{R})/2 and Bᵢ^{W}=(bᵢ^{R}−bᵢ^{L})/2 as a center and a halfwidth of a given interval constant Bᵢ corresponding to the i-th constraint performance function gᵢ(d, X, U), and defining an interval angular vector of the constant Bᵢ as a_{B}_{ᵢ}=(Bᵢ^{C}, Bᵢ^{W}), with a norm of ∥a_{B}_{ᵢ}∥;
3.2.2) calculating a feasibility robustness index of the i-th constraint performance function gᵢ(d, X, U) by Eq. 15:
$${S}_{i} = \{ \begin{matrix}1 - \frac{t r}{2} ( 1 - \frac{‖ {α}_{{G}_{i}^{S}} \times {α}_{{B}_{i}} ‖}{‖ {α}_{{G}_{i}^{S}} ‖ \cdot ‖ {α}_{{B}_{i}} ‖} ) - bia , {α}_{{B}_{i}} \neq ( 0 , 0 ) \\ 1 - \frac{t r}{2} ( 1 - \frac{‖ {α}_{{G}_{i}^{S}} \times {e}_{j} ‖}{‖ {α}_{{G}_{i}^{S}} ‖ \cdot ‖ {e}_{j} ‖} ) - bia , {α}_{{B}_{i}} \neq ( 0 , 0 )\end{matrix} , \qquad Eq . 15$$
wherein in Eq. 15, Sᵢ is the feasibility robustness index of the i-th constraint performance function gᵢ(d, X, U); eⱼ=(0, 1) is a unit vector; tr and bia respectively are a switch factor and a bias factor, which are calculated by Eq. 16:
$$\{ \begin{matrix}tr = \frac{1}{2} [ sign ( {g}_{i}^{{R}^{*}} ( d , X , U ) - {b}_{i}^{L} ) ( {b}_{i}^{R} - {g}_{i}^{{L}^{*}} ( d , X , U ) ) + 1 ] \\ bia = \frac{1}{2} [ sign ( {g}_{i}^{{L}^{*}} ( d , X , U ) - {b}_{i}^{R} ) + 1 ]\end{matrix} , \qquad Eq . 16$$
wherein, in Eq. 16, sign(⋅) is a sign function;
3.2.3) calculating, based on the feasibility robustness index of each constraint performance function, a total feasibility robustness index S of an individual by Eq. 17:
$$S = {\sum }_{i = 1}^{p} {S}_{i} , \qquad Eq . 17$$
wherein in Eq. 17, Sᵢ is the feasibility robustness index of the i-th constraint performance function gᵢ(d, X, U), and p is a number of the constraint performance functions.

4. The robust optimization design method for the mechanical arm based on the hybrid interval and bounded probabilistic uncertainties according to claim 1, wherein step 3.5) comprises:
3.5.1) calculating the DNIS of each feasible individual respectively, and calculating the DNIS D*(d) of an individual corresponding to the design vector d by Eq. 18:
$${D}^{*} ( d ) = \sqrt{\begin{matrix}\frac{{( {μ}_{max}^{C} - {μ}_{{f}^{C} ( d , X , U )} )}^{2}}{{μ}_{max}^{C} - {μ}_{min}^{C}} + \frac{{( {σ}_{max}^{C} - {μ}_{{f}^{C} ( d , X , U )} )}^{2}}{{μ}_{max}^{C} - {μ}_{min}^{C}} + \\ \frac{{( {μ}_{max}^{W} - {μ}_{{f}^{W} ( d , X , U )} )}^{2}}{{μ}_{max}^{W} - {μ}_{min}^{W}} + \frac{{( {σ}_{max}^{W} - {μ}_{{f}^{W} ( d , X , U )} )}^{2}}{{μ}_{max}^{W} - {μ}_{min}^{W}}\end{matrix}} , \qquad Eq . 18$$
wherein parameters in Eq. 18 are defined by Eq. 19:
$$\{ \begin{matrix}{μ}_{min}^{C} = min \{ {μ}_{{f}^{C} ( {d}_{1} , X , U )} , {μ}_{{f}^{C} ( {d}_{2} , X , U )} , … , {μ}_{{f}^{C} ( {d}_{{n}_{1}} , X , U )} \} \\ {μ}_{max}^{C} = max \{ {μ}_{{f}^{C} ( {d}_{1} , X , U )} , {μ}_{{f}^{C} ( {d}_{2} , X , U )} , … , {μ}_{{f}^{C} ( {d}_{{n}_{1}} , X , U )} \} \\ {σ}_{min}^{C} = min \{ {σ}_{{f}^{C} ( {d}_{1} , X , U )} , {σ}_{{f}^{C} ( {d}_{2} , X , U )} , … , {σ}_{{f}^{C} ( {d}_{{n}_{1}} , X , U )} \} \\ {σ}_{max}^{C} = max \{ {σ}_{{f}^{C} ( {d}_{1} , X , U )} , {σ}_{{f}^{C} ( {d}_{2} , X , U )} , … , {σ}_{{f}^{C} ( {d}_{{n}_{1}} , X , U )} \} \\ {μ}_{min}^{W} = min \{ {μ}_{{f}^{W} ( {d}_{1} , X , U )} , {μ}_{{f}^{W} ( {d}_{2} , X , U )} , … , {μ}_{{f}^{W} ( {d}_{{n}_{1}} , X , U )} \} \\ {μ}_{max}^{W} = max \{ {μ}_{{f}^{W} ( {d}_{1} , X , U )} , {μ}_{{f}^{W} ( {d}_{2} , X , U )} , … , {μ}_{{f}^{W} ( {d}_{{n}_{1}} , X , U )} \} \\ {σ}_{min}^{W} = min \{ {σ}_{{f}^{W} ( {d}_{1} , X , U )} , {σ}_{{f}^{W} ( {d}_{2} , X , U )} , … , {σ}_{{f}^{W} ( {d}_{{n}_{1}} , X , U )} \} \\ {σ}_{max}^{W} = max \{ {σ}_{{f}^{W} ( {d}_{1} , X , U )} , {σ}_{{f}^{W} ( {d}_{2} , X , U )} , … , {σ}_{{f}^{W} ( {d}_{{n}_{1}} , X , U )} \}\end{matrix} , \qquad Eq . 19$$
wherein in Eq. 19, d₁, d₂, . . . , dₙ_{₁} are all design vectors corresponding to the feasible individuals in the current population, and n₁ is a total number of the feasible individuals;
3.5.2) ranking the feasible individuals and the semi-feasible individuals, so that each individual participating in the ranking obtains a unique sequence number and an individual with inferior objective or constraint performance robustness has a larger sequence number, specifically:
a) ranking the feasible individuals in a descending order of the DNIS D*(d) from largest to smallest, wherein a smaller D*(d) indicates an inferior objective performance and a larger sequence number of the corresponding feasible individual, that is, the sequence numbers of the feasible individuals dₐ₁, dₐ, . . . , dₐₙ_{₁} satisfying D*(dₐ₁)≥D*(dₐ₂)≥ . . . ≥D*(dₐₙ_{₁}) are 1, 2, . . . , n₁ respectively; n₁ is a number of the feasible individuals in the current population; a indicates that the individual is feasible;
b) ranking the semi-feasible individuals in a descending order of the total feasibility robustness index S from largest to smallest, wherein a smaller S indicates that the corresponding semi-feasible individual has inferior robustness in the constraint performance function and has a higher sequence number; when the feasible individuals and the semi-feasible individuals are ranked, the sequence number of a first semi-feasible individual closely follows the sequence number of a last feasible individual; the sequence numbers of the two types of individuals are continuous, and the sequence numbers of the semi-feasible individuals are greater than the sequence numbers of the feasible individuals, that is, the sequence numbers of the semi-feasible individuals d_{b1}, d_{b2}, . . . , d_{bn}_{₂} satisfying S(d_{b1})≥S(d_{b2})≥ . . . ≥S(d_{bn}_{₂}) are (n₁+1), (n₁+2), . . . , (n₁+n₂) respectively; n₂ is a number of the semi-feasible individuals in the current population; b indicates that the individual is semi-feasible; and
3.5.3) calculating the fitness of each individual in the current population: a) calculating the fitness of a feasible individual or a semi-feasible individual according to its sequence number of ranking in step 3.5.2), and setting the fitness of a design vector with a sequence number i to 1/i; and b) setting the fitness of every infeasible individual to 0.
